(19) United States
(12) Patent Application Publication
(10) Pub. No.: US 2024/0355957 A1
(43) Pub. Date: Oct. 24, 2024

(54) METHOD FOR PRODUCING MICRO SEMICONDUCTOR LIGHT-EMITTING DIODE STRUCTURES, AND SEMICONDUCTOR LIGHT-EMITTING DIODE

(71) Applicant: ams-OSRAM International GmbH, Regensburg (DE)

(72) Inventors: Adrian Stefan Avramescu, Regensburg (DE); Laura Kreiner, Regensburg (DE); Andreas Lex, Zandt (DE)

(21) Appl. No.: 18/721,539

(22) PCT Filed: Dec. 14, 2022
(86) PCT No.: PCT/EP2022/085841

§ 371 Date: Jun. 18, 2024

(30) Foreign Application Priority Data
Dec. 21, 2021 (DE) 10 2021 134 107.8

(51) Int. Cl. H01L 33/00; H01L 27/15; H01L 33/32; H01L 33/58

(52) U.S. Cl. CPC H01L 33/0075; H01L 27/153; H01L 33/32; H01L 33/58

(57) ABSTRACT

In an embodiment a method for producing a plurality of micro semiconductor LED structures in a wafer includes epitaxially growing a semiconductor layer over a growth substrate wafer, applying a hard-mask material layer over the semiconductor layer, wherein a hard-mask material layer includes a plurality of adjacently arranged windows facing towards the semiconductor layer, introducing depressions into the semiconductor layer in the windows by sublimation and epitaxially growing a semiconductor light-emitting diode structure in each of the depressions.

### CROSS-REFERENCE TO RELATED APPLICATIONS

This patent application is a national phase filing under section 371 of PCT/EP2022/085841, filed Dec. 14, 2022, which claims the priority of German patent application 102021134107.8, filed Dec. 21, 2021, each of which is incorporated herein by reference in its entirety.

### TECHNICAL FIELD

The present disclosure relates to a method for producing micro semiconductor light-emitting diode structures (hereinafter referred to as “micro semiconductor LED structures”). The present disclosure further relates to a semiconductor light-emitting diode (hereinafter referred to as “semiconductor LED”) having micro semiconductor LED structures.

### SUMMARY

Embodiments provide a method which makes it possible to produce a plurality of micro semiconductor LED structures on a wafer with structure sizes in the single-digit μm range, i.e. with structure sizes of less than 10 μm, and with distances between them in the single-digit μm range, i.e. with distances between them of less than 10 μm. Such small semiconductor LED structures are used in particular in so-called pixelated μLEDs.

The term “structure size” refers in particular to the distance between the centers of two adjacent micro semiconductor LED structures.

Further embodiments provide a micropixelated semiconductor LED, i.e. a micropixelated semiconductor light-emitting diode chip (semiconductor LED chip), which is comparatively easy to manufacture.

With the method described here, it is possible to provide micro semiconductor LED structures with particularly small distances between their flanks. For example, distances of 5 μm down to 100 nm and even less can be achieved.

According to at least one embodiment of the method for producing a plurality of micro semiconductor LED structures in a wafer, a growth substrate wafer is provided on which a semiconductor layer is grown epitaxially. A hard-mask material layer is subsequently applied on the semiconductor layer.

This hard-mask material layer is then structured, for example using a photolithographic method, such that a hard mask with a plurality of adjacently arranged windows is formed. The windows each penetrate the hard-mask material layer right down to the semiconductor layer.

Depressions are then introduced into the semiconductor layer through the windows by sublimation of the semiconductor layer material. A plurality of depressions is formed in the semiconductor layer corresponding to the plurality of windows.

A micro semiconductor LED structure is then epitaxially grown in each of the depressions. A plurality of micro semiconductor LED structures are thus formed simultaneously in the depressions.

According to at least one embodiment of the method, the sublimation of the material of the semiconductor layer in the windows of the hard-mask material layer takes place, for example, at temperatures between 850° C. and 1500° C., preferably between 1000° C. and 1500° C.

According to at least one embodiment of the method or its aforementioned embodiments, a nitride-based semiconductor layer is grown on the growth substrate wafer. The growth substrate wafer comprises, for example, sapphire or GaN, and in particular consists of sapphire or GaN.

According to at least one embodiment of the method or its aforementioned embodiments, the nitride-based semiconductor layer comprises, for example, a semiconductor layer sequence with a first semiconductor sublayer of a first conductivity type facing the substrate and a second semiconductor sublayer arranged downstream of the first semiconductor sublayer as viewed from the substrate, said second semiconductor sublayer being undoped.

According to at least one embodiment of the aforementioned method, the first semiconductor sublayer comprises n-GaN, for example. According to at least one embodiment, the second semiconductor sublayer comprises intrinsic GaN, for example.

According to at least one embodiment of the method or its aforementioned embodiments, depressions are produced which have lateral boundary surfaces which are essentially perpendicular to the main extension plane of the growth substrate wafer.

According to at least one embodiment of the method or its aforementioned embodiments, the lateral boundary surfaces of the depressions extend along crystallographic axes of the semiconductor layer material adjacent to the depressions.

According to at least one embodiment of the method or its aforementioned embodiments, the semiconductor layer is formed with GaN-based material, and the depressions each have a hexagonal cross-section in a plane lying essentially parallel to the main extension plane of the growth substrate wafer.

According to at least one other embodiment of the method or its aforementioned embodiments, the semiconductor layer is formed with GaN-based material, and the depressions each have a line-like cross-section in a plane lying essentially parallel to the main extension plane of the growth substrate wafer.

According to at least one embodiment of the semiconductor LED, a plurality of micro semiconductor LED structures arranged adjacently at a distance from one another is provided. Each micro semiconductor LED structure is grown epitaxially in a depression of a semiconductor layer grown epitaxially on a growth substrate. In other words, the semiconductor layer has a plurality of depressions corresponding to the plurality of micro semiconductor LED structures, in which depressions the plurality of micro semiconductor LED structures are epitaxially grown.

According to at least one embodiment of the semiconductor LED, there is a hard-mask material layer on the semiconductor layer. The hard-mask material layer has a window in each of the positions of the micro semiconductor LED structures. In other words, on the semiconductor material layer, there is a hard-mask material layer having a plurality of windows in the same pattern as the pattern of the plurality of depressions in the semiconductor layer and thus the plurality of micro semiconductor LED structures.

According to at least one embodiment of the aforementioned embodiment, the micro semiconductor LED structures have radiation outcoupling surfaces facing away from the growth substrate. These radiation outcoupling surfaces form an essentially flat surface with the side of the semiconductor layer facing away from the growth substrate or, if applicable, with the side of the hard-mask material layer facing away from the growth substrate. For example, the height of the micro semiconductor LED structures is essentially identical to the depth of the depressions in the semiconductor layer, possibly including the associated window of the hard-mask material layer.

According to at least one embodiment of the aforementioned embodiment, optical elements, such as lens structures, or meta-optical elements, such as meta-lenses, are arranged on the essentially planar surface above the micro semiconductor LED structures. Such optical elements can be applied to an essentially planar surface in a simple manner.

The term “essentially” in this context expresses that the height may deviate from the sum of the above-mentioned depth and thickness within the scope of the usual production tolerances familiar to the person skilled in the art but is nevertheless still to be regarded as practically identical to the latter. In other words, the height of the micro semiconductor LED structures is nominally equal to the sum of the above-mentioned depth and thickness but can deviate slightly from each other to a technically insignificant extent within the scope of production tolerances that exist in practice.

According to at least one other embodiment of the semiconductor LED, the micro semiconductor LED structures protrude from the depressions, including the associated window of the hard-mask material layer, if applicable.

According to yet at least one other embodiment of the semiconductor LED, radiation outcoupling surfaces of the micro semiconductor LED structures facing away from the growth substrate are located below the side of the semiconductor layer or, if applicable, the hard-mask material layer facing away from the growth substrate wafer. In other words, the radiation outcoupling surfaces of the micro semiconductor LED structures facing away from the growth substrate may be set back with respect to the side of the semiconductor layer or, if applicable, the hard-mask material layer facing away from the growth substrate.

According to at least one embodiment of the semiconductor LED or its aforementioned embodiments, the micro semiconductor LED structures have light outcoupling surfaces facing away from the growth substrate and being at least partially convexly curved.

According to at least one embodiment of the method or its aforementioned embodiments or the semiconductor LED or its aforementioned embodiments, the micro semiconductor LED structures each comprise a first semiconductor region of a first conductivity type, an active zone, and a second semiconductor region of a second conductivity type. The active zone is arranged between the first semiconductor region and the second semiconductor region. The active zone preferably contains a p-n junction, a single quantum well structure or a multiple quantum well structure for generating electromagnetic radiation.

The micro semiconductor LED structures are preferably based on a III-V semiconductor compound material, particularly preferably on a nitride compound semiconductor material such as AlₙIn₁₋ₙ₋ₘGaₘN, where in each case 0≤n≤1, 0≤m≤1 and n+m≤1. Preferably, 0<n≤0.8, 0.4≤m<1 and n+m≤0.95 applies to at least one layer or to all layers of the micro semiconductor LED structures. The micro semiconductor LED structures can comprise dopants and additional components. For the sake of simplicity, however, only the essential components of the crystal lattice of the semiconductor layer sequence, i.e. Al, Ga, In, N, are specified, even if these may be partially replaced and/or supplemented by small amounts of other substances.

In principle, the method or micro semiconductor LED structure described herein is also applicable to GaP-based micro semiconductor LED structures.

Until now, so-called pixels of micro semiconductor LEDs (“μLEDs”), as the above-mentioned micro semiconductor LED structures are also referred to, have typically only been defined after the epitaxial growth of a semiconductor layer sequence of the subsequent micro semiconductor LED structures on a growth substrate wafer in the subsequent chip process. In other words, a semiconductor layer sequence for micro semiconductor LED structures is essentially grown epitaxially over the entire wafer and this semiconductor layer sequence is subsequently structured so as to form a plurality of micro semiconductor LED structures arranged at a distance from one another. Due to the resulting oblique flank angles, the distance between the micro semiconductor LED structures does not fall below a certain minimum.

There is an ever-increasing demand for μLEDs, especially III-nitride μLEDs, for a wide range of applications, such as car displays, next-generation TVs, microdisplays for smartphones and smartwatches, and augmented reality and virtual reality (AR and VR) applications.

III-nitride μLEDs have a number of advantageous properties compared to conventional organic LEDs (OLEDs) and liquid crystal displays (LCDs). III-nitride microdisplays with μLEDs have a high resolution combined with high efficiency and a high contrast ratio, a long operating life and chemical robustness. LCDs, on the other hand, are not self-emitting and therefore not as efficient and also not as highly resolving. In order to achieve an appropriate service life, OLEDs are operated in practice with a very low injection current density, which is several orders of magnitude lower than that of semiconductor LEDs.

Next-generation car displays and TVs require μLED dimensions of <100 μm (the smaller the better). For microdisplays for smartphones and smartwatches, μLEDs with a dimension of <50 μm (again, the smaller the better; ideally ≤10 μm) and for AR/AV applications, μLEDs with a dimension of <5 μm are desirable.

μLEDs can also be used for high-speed data transmission with a GHz modulation bandwidth for visible light communication (VLC applications). This is because their junction capacitance is significantly reduced compared to current standard LEDs due to the smaller dimensions.

III nitride μLEDs have so far been produced in practice using a combination of a standard photolithography technique and

subsequent dry etching processes on a standard III-nitride LED wafer. A dry etching process generally generates surface damages that increase non-radiative recombination, which leads to a reduction in optical performance.

This problem is of secondary importance for large-area LEDs with dimensions >100 μm and can be ignored there.

However, this problem becomes increasingly serious as the LED dimension decreases and can ultimately become a factor that leads to a severe deterioration in optical performance.

Although passivation of the side walls with dielectric materials can reduce the plasma-induced damages to μLEDs during dry etching to a certain extent, this improvement is only marginal, even if atomic layer deposition (ALD) is used for surface passivation instead of standard plasma-enhanced chemical vapor deposition (PECVD).

In this case, the passivation process generates an additional problem, namely the etching back of the dielectric layer on the p-contact/p-GaN. This worsens the electrical injection in the p-GaN area, which represents an additional challenge.

Overcoming these limitations is an object underlying the method and the semiconductor LED described here.

In order to overcome the problems mentioned above, a fundamental change in the procedure for producing ultra-small, ultra-efficient and ultra-compact micro semiconductor LED structures is presented here. This enables the production of micro semiconductor LED structures with a dimension of less than 5 μm and an interpitch of less than 3 μm. The micro semiconductor LED structures are grown epitaxially within depressions in the semiconductor layer using a selective overgrowth method. The necessary depressions in the semiconductor layer are introduced into the semiconductor layer by sublimation through windows in a hard mask located on the semiconductor layer, for example a pre-structured SiO₂ microhole array with a hole diameter of 3.6 μm and a hole spacing of 2 μm. Subsequently, the semiconductor LED structures are epitaxially grown in the depressions, in particular simultaneously.

An exemplary method for producing an SiO₂ microhole array on a semiconductor layer that can be used in the method described herein is described, for example, in the article “A Direct Epitaxial Approach to Achieving Ultrasmall and Ultrabright InGaN Micro Light-Emitting Diodes (μLEDs)” by Jie Bai et al, ACS Photonics 2020, 7, 411-415, on p. 412, left column, last line, to right column, eleventh line, whose relevant disclosure is incorporated herein by reference. This article is incorporated herein by reference in its entirety.

An exemplary method for selective sublimation of a GaN-based semiconductor layer is described, for example, in the article “Selective Area Sublimation: A Simple Top-down Route for GaN-Based Nanowire Fabrication” by B. Damilano et al, Nano Lett. 2016, 16, 1863-1868, (hereinafter referred to as “Damilano et al” for short), the disclosure of which is incorporated herein by reference. This article is incorporated herein by reference in its entirety.

In the article “A Direct Epitaxial Approach To Achieving Ultrasmall and Ultrabright InGaN Micro Light-Emitting Diodes (μLEDs)” by Jie Bai et al in ACS Photonics 2020, 7, 411-415, (hereinafter referred to as “Jie Bai et al” for short) a method is proposed, in which a conventional silicon-doped n-GaN layer with a thickness of 1.5 μm is first grown on a sapphire growth substrate by any standard GaN growth method using, for example, metal organic vapor phase epitaxy (MOVPE). A dielectric SiO₂ layer with a thickness of 500 nm is then formed on the n-GaN layer using a standard PECVD method. This is selectively etched down to the n-GaN surface using a photolithography technique and subsequent etching. For example, using a standard method with inductively coupled plasma (ICP), with a mixture of Cl₂ with a flow rate of 20 sccm and Ar with a flow rate of 30 sccm under a pressure of 35 mTorr at an etching power of 250 W. Using this simple method, regularly arranged microholes with a diameter of 3.6 μm and a spacing of 2 μm are formed in the dielectric SiO₂ layer. Subsequently, a standard III-nitride LED structure is grown on the GaN substrate masked with the SiO₂ microhole mask by MOVPE. The total thickness of the overgrown structures, i.e. the standard III-nitride LED structures, is approximately 500 nm, which corresponds to the thickness of the SiO₂ mask. In this method, the standard III-nitride LED structures are therefore selectively grown within the microholes of the dielectric SiO₂ layer. μLED mesa etching processes are therefore not required. This means that the dimension, individual position, shape and interpitch of the standard III-nitride LED structures generated in this way are completely controlled by the SiO₂ mask. One problem with this method or these LED structures is that there are many defects at the edge of the SiO₂ that cause non-radiative recombination.

In the method presented in this patent application, dry etching processes for the formation of μLED mesas, as used in conventional practical production methods, are also eliminated.

In an advantageous embodiment of the method described herein, a GaN semiconductor layer is first epitaxially grown on a suitable growth substrate wafer such as a sapphire wafer or a GaN wafer. For example, using a conventional MOVPE method such as that outlined in Jie Bai et al.

Subsequently, a hard-mask material layer, for example an SiO₂ hard-mask material layer, is applied on the GaN semiconductor layer. For example, using a conventional PECVD method such as that outlined in Jie Bai et al.

Subsequently, the hard-mask material layer is provided with a microhole structure. For example, using a photolithography technique and subsequent etching as outlined in Jie Bai et al.

The microholes form windows in the hard-mask material layer towards the GaN semiconductor layer.

By means of a sublimation process as outlined, for example, in Damilano et al, depressions are structured into the semiconductor layer through the microholes, wherein depressions with sidewalls essentially perpendicular to the main extension plane of the growth substrate can be achieved if the sublimation parameters are set appropriately. Micro semiconductor LED structures are then grown epitaxially in the depressions, for example using MOVPE and using a method such as that outlined in Jie Bai et al.

Alternatively, the geometric shape of the micro semiconductor LED structures (pixels) can be controlled by the ratio of the growth rates on the sidewalls, which are essentially perpendicular to the main extension plane of the wafer, and on the horizontal base area of the semiconductor layer via the growth parameters. As a result, the sidewalls, which may have numerous defects due to the sublimation process, can also be overgrown. For example, in a first epitaxial growth step for generating the micro semiconductor LED structures, the speed of lateral growth can be selected to be much greater than the speed of vertical growth in order to initially provide the essentially vertical sidewalls with a semiconductor layer with fewer defects. In a second epitaxial growth step, the speed of lateral growth can be selected to be approximately equal to the speed of vertical growth, for example in order to generate depressions for the other layers of the micro semiconductor LED structures, which have oblique flanks relative to the side walls of the depressions originally generated by sublimation. The geometry of the flanks of the micro semiconductor LED structures can therefore be specifically varied by selecting suitable growth parameters.

If the epitaxial growth of the micro semiconductor LED structures cannot be stopped exactly at the level of the hard mask, a subsequent planarization step can be added. A CMP process can be used for this purpose, for example.

However, even without this additional process, the method described here can be used to ensure that there are only minor height differences on the wafer after the micro semiconductor LED structures have been grown. This facilitates subsequent chip processes. For example, lenses can be structured precisely over the individual micro semiconductor LED structures in order to improve light extraction and the spatial distribution of the far field.

As said before, using a method described here, micro semiconductor LED structures with flanks that are essentially perpendicular to the main extension plane of the wafer can be achieved. The pixels with the LED structure (p, n and QW) are grown in the depressions created. This allows very small pixels to be defined at short distances from each other.

Using the method described here, the micro semiconductor LED structures are embedded in semiconductor material, allowing the chip process to be started with a flat wafer and resulting in less leakage.

In order to be able to grow the individual micro semiconductor LED structures in the depressions with few defects, the structures predefined by the windows in the hard-mask material layer are structured in the surrounding semiconductor material of the semiconductor layer along crystallographic axes of the semiconductor material. Therefore, in the case of GaN semiconductor material, hexagonal or linear structures are particularly suitable here, which then also specify the geometry of the cross-section of the micro semiconductor LED structures, wherein the cross-section meant here is essentially perpendicular to the growth direction, i.e. essentially parallel to the main extension plane of the growth substrate wafer.

In summary, the method described here offers the following advantages in particular:

A flat wafer with a very low topography and defined micro semiconductor LED structures is achieved after the epitaxy process.

Areas between the micro semiconductor LED structures are already electrically insulated by masking.

Vertical side walls of the individual micro semiconductor LED structures are possible with this structuring technology, allowing small micro semiconductor LED structures to be produced at short distances from each other.

Fewer defects in side walls and therefore less leakage.

Sublimation can take place in-situ directly before the subsequent growth of the micro semiconductor LED structures and therefore has advantages over etching.

The geometry of the micro semiconductor LED structures can, for example, be optimized for good outcoupling by suitably coordinating lateral and vertical growth (e.g. with a rounded geometry).

Combination with additional optical elements is easily possible due to the possible flat wafer surface (for example by means of targeted structuring of defined lens structures over individual pixels or by means of meta-optical elements).

### BRIEF DESCRIPTION OF THE DRAWINGS

In the following, a method described herein and a semiconductor LED described herein are explained in more detail with reference to schematic drawings on the basis of exemplary embodiments and further developments thereof.

Identical reference signs indicate identical elements in the various figures.

In principle, the drawings do not show any true-scale relations, but individual elements may be shown in exaggerated size to make them easier to understand or recognize.

FIG. 1 is a schematic sectional view of a wafer in a first intermediate stage of an exemplary embodiment of a method described herein;

FIG. 2 is a schematic sectional view of a wafer in a second intermediate stage of the exemplary embodiment of a method described herein;

FIG. 3 is a schematic sectional view of a wafer in a third intermediate stage of the exemplary embodiment of a method described herein;

FIG. 4 is a schematic sectional view of a wafer in a fourth intermediate stage of the exemplary embodiment of a method described herein;

FIG. 5 is a schematic sectional view of a first semiconductor light-emitting diode structure as can be produced by a method according to the exemplary embodiment;

FIG. 6 is a schematic sectional view of a further development of the first semiconductor light-emitting diode structure shown in FIG. 5;

FIG. 7 is a schematic sectional view of a second semiconductor light-emitting diode structure as can be produced by a method according to the exemplary embodiment; and

FIG. 8 is a schematic sectional view of a third semiconductor light-emitting diode structure as can be produced by a method according to the exemplary embodiment.

### DETAILED DESCRIPTION OF ILLUSTRATIVE EMBODIMENTS

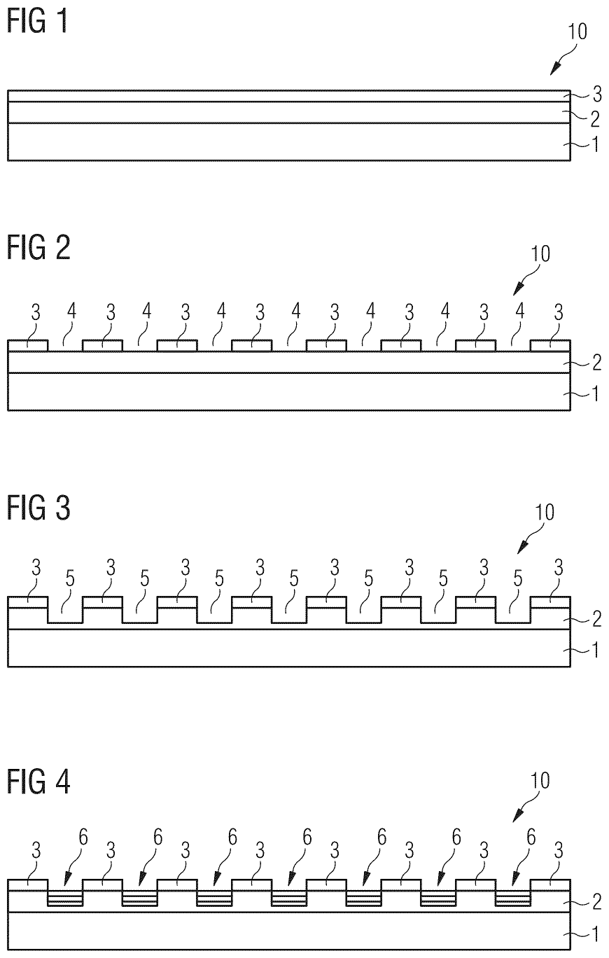

In the exemplary embodiment of the method described here, an undoped, i.e. intrinsic GaN semiconductor layer 2 is first grown over an n-GaN growth substrate wafer 1, for example using MOVPE. The intrinsic GaN semiconductor layer 2 has a thickness of between 50 nm and 1 μm, preferably between 100 nm and 300 nm, depending on the intended micro semiconductor LED structure. An SiO₂ hard-mask material layer 3 with a thickness of approx. 500 nm is then formed on the GaN semiconductor layer 2, for example using a standard PECVD method. The wafer 10 generated in this way is shown schematically in a sectional view in FIG. 1. In an exemplary implementation (not shown) of the exemplary embodiment, at least one further semiconductor layer, for example an n-aluminum gallium nitride layer, is arranged between the growth substrate wafer 1 and the intrinsic GaN semiconductor layer 2. Such a further semiconductor layer can be used, for example, to specifically influence the bottom-side geometry of the depressions. In an exemplary implementation (not shown) of the exemplary embodiment or its aforementioned implementation, the intrinsic semiconductor layer is formed with several semiconductor layers, i.e. the intrinsic semiconductor layer is a semiconductor layer sequence.

In other implementations of the exemplary embodiment (not shown here), the hard-mask material layer 3 sometimes has a thickness of between 30 nm and 500 nm, in particular between 50 nm and 150 nm, depending on the configuration of the subsequent process steps. Instead of SiO₂, a different suitable hard-mask material can be used, for example silicon nitride.

For example, a pure n-GaN wafer is conceivable as an n-GaN growth substrate wafer 1, as well as a two-or multilayer wafer, for example with a self-supporting sapphire substrate and an n-GaN layer applied to it, which then represents the actual n-GaN growth substrate.

The hard-mask material layer 3 is then structured selectively right down to the GaN semiconductor layer 2, for example by means of a photolithography technique and subsequent etching. For example, using a standard method with inductively coupled plasma (ICP), with a mixture of Cl₂ having a flow rate of 20 sccm and Ar having a flow rate of 30 sccm under a pressure of 35 mTorr at an etching power of 250 W. This method is used, for example, to form regularly arranged microholes with a diameter of 4 μm, for example, and a spacing of 3 μm, for example. The microholes form windows 4 in the hard-mask material layer towards the GaN semiconductor layer 2. A method for producing such a hard-mask material layer 3 with microholes (windows 4) is outlined, for example, in Jie Bai et al. The resulting wafer 10 is shown schematically in a sectional view in FIG. 2.

Subsequently [MK₁], by means of a sublimation process as outlined in principle in Damilano et al, for example, depressions 5 are structured into the GaN semiconductor layer 2 through the windows 4, wherein, with suitable adjustment of the sublimation parameters, depressions 5 with side walls essentially perpendicular to the main extension plane of the wafer 10 can be achieved. The resulting wafer 10 is shown schematically in a sectional view in FIG. 3.

Subsequently, micro semiconductor LED structures 6 are epitaxially grown in the depressions 5, for example using a MOVPE method as outlined in Jie Bai et al, for example. Here, standard III-nitride LED structures are grown as micro semiconductor LED structures 6 on the exposed surfaces of the n-GaN growth substrate wafer 1 in the depressions 5 using a MOVPE method. To generate the standard III-nitride LED structures, a silicon-doped n-GaN layer is first grown in each of the depression 5, followed by an InGaN-based (5% indium content) pre-layer, five periods of InGaN/GaN multiple quantum wells (MQWs) with 2.5 nm InGaN quantum wells and 13.5 nm GaN barriers as the active layer, a 20 nm thick p-Al_{0.2}Ga_{0.8}N barrier layer and finally a 200 nm thick p-GaN layer. The resulting wafer 10 is shown schematically in a sectional view in FIG. 4.

In a further development of the method according to the exemplary embodiment, the lateral boundary surfaces of the depressions run along crystallographic axes of the material of the semiconductor layer 2. As a result, micro semiconductor LED structures 6 can be grown with few defects. In the case of a GaN semiconductor layer 2, the depressions 5, which define the geometry of the micro semiconductor LED structures 6, each advantageously have a hexagonal cross-section parallel to the main extension plane of the growth substrate 1 or an elongated rectangular, i.e. line-like, cross-section.

An exemplary embodiment of a semiconductor LED 7 described here, which has been produced, for example, by a method according to the exemplary embodiment described above, has a plurality of micro semiconductor LED structures 6 arranged adjacently at a distance to one another. Each of the micro semiconductor LED structures 6 is epitaxially grown on a growth substrate 1 in a specially provided depression 5 spaced apart from adjacent depressions 5 of an epitaxially grown semiconductor layer 2. Schematic illustrations of sections of such semiconductor light-emitting diodes are shown in FIGS. 5 to 8.

In a further development of the exemplary embodiment of the semiconductor LED, the micro semiconductor LED structures 6 have radiation outcoupling surfaces 8 facing away from the growth substrate 1. The radiation outcoupling surfaces 8 form an essentially flat surface with the side of the semiconductor layer 2 facing away from the growth substrate 1 or, if applicable, a side of a hard-mask material layer 3 arranged on the semiconductor layer 2 facing away from the growth substrate 1. A schematic illustration of a section of such a semiconductor LED is shown in FIG. 5.

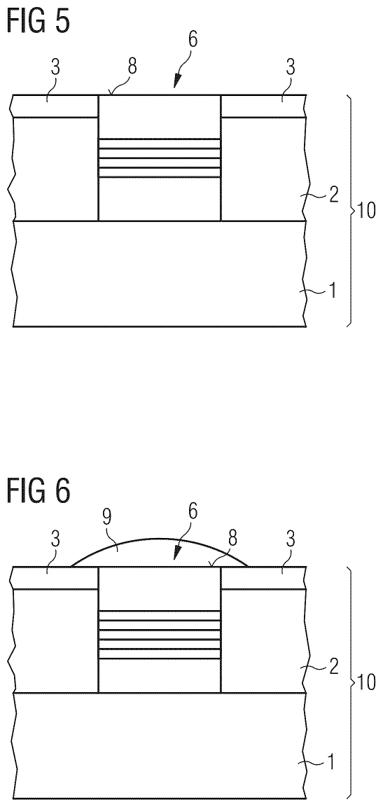

In a semiconductor LED of this type, as illustrated in FIG. 6, it is possible in a simple manner for optical or meta-optical elements 9 to be arranged on the semiconductor light-emitting diode structures 6.

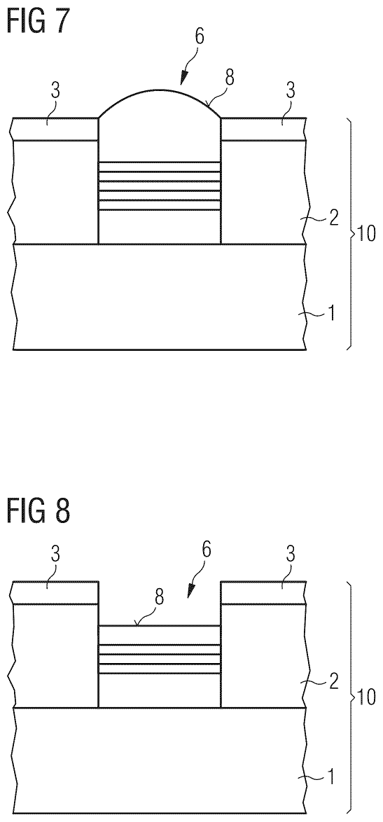

In another further development of the exemplary embodiment of the semiconductor LED, the micro semiconductor LED structures 6 protrude from the depressions 5 or from windows 4 of a hard-mask material layer 3 arranged on the semiconductor layer 2. The micro semiconductor LED structures 6 have at least partially convexly curved radiation outcoupling surfaces 8 facing away from the growth substrate 1. A schematic illustration of a section of such a semiconductor LED is shown in FIG. 7.

In yet another further development of the exemplary embodiment of the semiconductor LED, radiation outcoupling surfaces 8 of the micro semiconductor LED structures 6 are set back as seen from the growth substrate 1 with respect to a side of the semiconductor layer 2 or, if applicable, the hard-mask material layer 3 facing away from the growth substrate 1. A schematic illustration of a section of such a semiconductor LED is shown in FIG. 8. The radiation outcoupling surfaces 8 can also be at least partially convexly curved.

In all the exemplary embodiments and further developments of the semiconductor LED described above, the growth substrate 1, the semiconductor layer 2 and the micro semiconductor LED structures 3 are formed, for example, with semiconductor materials based on nitride compound semiconductor material, as already described in more detail above.

In the present context, “semiconductor material based on nitride compound semiconductor material” generally preferably comprises AlₙGaₘIn₁₋ₙ₋ₘN, with 0≤n≤1, 0≤m≤1 and n+m≤1. This material does not necessarily have to have a mathematically exact composition according to the above formula. Rather, it can, for example, have one or more dopants as well as additional constituents. For the sake of simplicity, however, the above formula only contains the essential constituents of the crystal lattice (Al, Ga, In, N), even if these may be partially replaced and/or supplemented by small amounts of other substances.

Unless indicated otherwise, the components shown in the figures preferably follow each other directly in the specified sequence. Where lines are drawn parallel to each other, the corresponding surfaces are preferably also aligned parallel to each other. Likewise, unless indicated otherwise, the relative positions of the drawn components to each other are shown correctly in the figures.

The term “essentially” used above in several places in different contexts, and its variants used are generally to be understood in the present case as corresponding to what a person skilled in the art would understand to be included in the following specific term as a result, for example in the context of production tolerances in practically available production methods. Accordingly, for example, “essentially vertical”, “essentially parallel”, “essentially the same height” etc. means that this also includes deviations from the nominal specifications “vertical”, “parallel”, “the same height”, etc. arising within the scope of the usual production tolerances of practically available production methods.

The method and the semiconductor LED described herein is not limited to the exemplary embodiments by the description based on the embodiments. Rather, the method described herein and the semiconductor LED described herein include any new feature as well as any combination of features, which includes in particular any combination of features in the patent claims, even if this feature or combination itself is not explicitly stated in the patent claims or embodiments.

1.-12. (canceled)

13. A method for producing a plurality of micro semiconductor LED structures in a wafer, the method comprising:
epitaxially growing a semiconductor layer over a growth substrate wafer;
applying a hard-mask material layer over the semiconductor layer, wherein the hard-mask material layer comprises a plurality of adjacently arranged windows facing towards the semiconductor layer;
introducing depressions into the semiconductor layer in the windows by sublimation; and
epitaxially growing a semiconductor light-emitting diode structure in each of the depressions.

14. The method according to claim 13, wherein the sublimation takes place at temperatures between 850° C. and 1500° C.

15. The method according to claim 13, wherein the semiconductor layer comprises a nitride-based semiconductor layer.

16. The method according to claim 15, wherein the nitride-based semiconductor layer comprises intrinsic GaN.

17. The method according to claim 16, wherein lateral boundary surfaces of the depressions extend along crystallographic axes of the material of the semiconductor layer.

18. The method according to claim 17, wherein the depressions have a hexagonal cross-section.

19. The method according to claim 17, wherein the depressions have a line-like cross-section.

20. The method according to claim 13, wherein the micro semiconductor LED structures are produced with semiconductor materials based on nitride compound semiconductor material.

21. A semiconductor light-emitting diode comprising:
a plurality of micro semiconductor LED structures arranged adjacently at a distance from one another,
wherein each of the plurality of micro semiconductor LED structures is grown epitaxially in a depression of a semiconductor layer grown epitaxially on a growth substrate, and
wherein the micro semiconductor LED structures have radiation outcoupling surfaces, which face away from the growth substrate and which form a flat surface with a side of the semiconductor layer facing away from the growth substrate or are set back with respect to the side of the semiconductor layer facing away from the growth substrate.

22. The semiconductor light-emitting diode according to claim 21, further comprising optical or meta-optical elements arranged on the micro semiconductor LED structures.

23. The semiconductor light-emitting diode according to claim 21, wherein the micro semiconductor LED structures comprise at least partially convexly curved radiation outcoupling surfaces facing away from the growth substrate.

24. The semiconductor light-emitting diode according to claim 21, wherein the growth substrate, the semiconductor layer and the micro semiconductor LED structures comprise semiconductor material based on nitride compound semiconductor material.

25. A semiconductor light-emitting diode comprising:
a plurality of micro semiconductor LED structures arranged adjacently at a distance from one another,
wherein each of the plurality of micro semiconductor LED structures is grown epitaxially in a depression of a semiconductor layer grown epitaxially on a growth substrate,
wherein the semiconductor layer is not an LED structure and the micro semiconductor LED structures have radiation outcoupling surfaces, which are facing away from the growth substrate and which form a flat surface with a side of the semiconductor layer facing away from the growth substrate.
